(19) United States
(12) Patent Application Publication
(10) Pub. No.: US 2026/0045282 A1
(43) Pub. Date: Feb. 12, 2026

(54) SEMICONDUCTOR DEVICE AND METHOD OF MANUFACTURING SEMICONDUCTOR DEVICE

(71) Applicant: Kioxia Corporation, Tokyo (JP)

(72) Inventor: Takumi MURAMATSU, Yokkaichi Mie (JP)

(73) Assignee: Kioxia Corporation, Tokyo (JP)

(21) Appl. No.: 19/075,861

(22) Filed: Mar. 11, 2025

(30) Foreign Application Priority Data
Aug. 6, 2024 (JP) 2024-129874

(51) Int. Cl. G11C 5/06; H01L 23/00; H10B 43/10; H10B 43/27

(52) U.S. Cl. CPC G11C 5/063; H01L 24/08; H10B 43/10; H10B 43/27; H01L 2224/08145; H01L 2924/1438

(57) ABSTRACT

A semiconductor device of an embodiment includes: a plurality of vias each includes: an upper structure connected to any one of a plurality of second wiring layers and extending above a plurality of air gap layers toward a plurality of first wiring layers, the upper structure having a first diameter larger than a width of each of the plurality of first wiring layers in a first direction intersecting an extending direction of the plurality of first wiring layers; and a lower structure extending at a height position of the plurality of air gap layers and connected to any one of the plurality of first wiring layers, the lower structure having a second diameter smaller than the first diameter.

### CROSS-REFERENCE TO RELATED APPLICATIONS

This application is based upon and claims the benefit of priority from Japanese Patent Application No. 2024-129874, filed on Aug. 6, 2024; the entire contents of which are incorporated herein by reference.

### FIELD

Embodiments described herein relate generally to a semiconductor device and a method of manufacturing a semiconductor device.

### BACKGROUND

In order to reduce the size of a semiconductor device, the distance and pitch between wirings have been reduced. Therefore, there is a concern that the capacitance between the wirings and the capacitance between the wiring and a via that connects the wirings to each other increase, and the breakdown voltage becomes insufficient.

### BRIEF DESCRIPTION OF THE DRAWINGS

FIGS. 1A and 1B are diagrams illustrating a schematic configuration example of a semiconductor device according to an embodiment;

FIGS. 2A to 2D are cross-sectional views illustrating an example of the configuration of the semiconductor device according to the embodiment;

FIGS. 3A to 3D are schematic diagrams illustrating an example of a layout of various configurations in a memory region of the semiconductor device according to the embodiment;

FIGS. 4A to 4C are diagrams sequentially illustrating a part of the procedure of a method of manufacturing the semiconductor device according to the embodiment;

FIGS. 5A and 5B are diagrams sequentially illustrating a part of the procedure of the method of manufacturing the semiconductor device according to the embodiment;

FIGS. 6A and 6B are diagrams sequentially illustrating a part of the procedure of the method of manufacturing the semiconductor device according to the embodiment;

FIGS. 7A and 7B are diagrams sequentially illustrating a part of the procedure of the method of manufacturing the semiconductor device according to the embodiment;

FIGS. 8A and 8B are diagrams sequentially illustrating a part of the procedure of the method of manufacturing the semiconductor device according to the embodiment;

FIGS. 9Aa to 9Bb are diagrams sequentially illustrating a part of the procedure of the method of manufacturing the semiconductor device according to the embodiment;

FIGS. 10Aa to 10Bb are diagrams sequentially illustrating a part of the procedure of the method of manufacturing the semiconductor device according to the embodiment;

FIGS. 11Aa to 11Bb are diagrams sequentially illustrating a part of the procedure of the method of manufacturing the semiconductor device according to the embodiment;

FIGS. 12A and 12B are diagrams sequentially illustrating a part of the procedure of the method of manufacturing the semiconductor device according to the embodiment;

FIGS. 13A and 13B are diagrams sequentially illustrating a part of the procedure of the method of manufacturing the semiconductor device according to the embodiment;

FIGS. 14A to 14D are diagrams sequentially illustrating a part of the procedure of the method of manufacturing the semiconductor device according to the embodiment;

FIGS. 15A to 15D are diagrams sequentially illustrating a part of the procedure of the method of manufacturing the semiconductor device according to the embodiment; and

FIGS. 16A to 16D are diagrams sequentially illustrating a part of the procedure of the method of manufacturing the semiconductor device according to the embodiment.

### DETAILED DESCRIPTION

A semiconductor device of an embodiment includes: a plurality of first wiring layers arranged at a predetermined distance from each other; a plurality of air gap layers respectively disposed between the plurality of first wiring layers so as to protrude from a height position of the first wiring layer, and extending along the first wiring layer; a plurality of second wiring layers disposed above the plurality of first wiring layers; and a plurality of vias extending from the plurality of second wiring layers to the plurality of first wiring layers between the plurality of air gap layers and connecting the plurality of first and second wiring layers, respectively, in which the plurality of vias each includes: an upper structure connected to any one of the plurality of second wiring layers and extending above the plurality of air gap layers toward the plurality of first wiring layers, the upper structure having a first diameter larger than a width of each of the plurality of first wiring layers in a first direction intersecting an extending direction of the plurality of first wiring layers; and a lower structure extending at a height position of the plurality of air gap layers and connected to any one of the plurality of first wiring layers, the lower structure having a second diameter smaller than the first diameter.

The embodiment of the present invention will be described below in detail with reference to the drawings. Note that the present invention is not limited to the following embodiments. The components in the following embodiments include those that can be readily assumed by those skilled in the art or those that are substantially identical.

### EMBODIMENT

The embodiment will be described below in detail with reference to the drawings.

### Configuration Example of Semiconductor Device

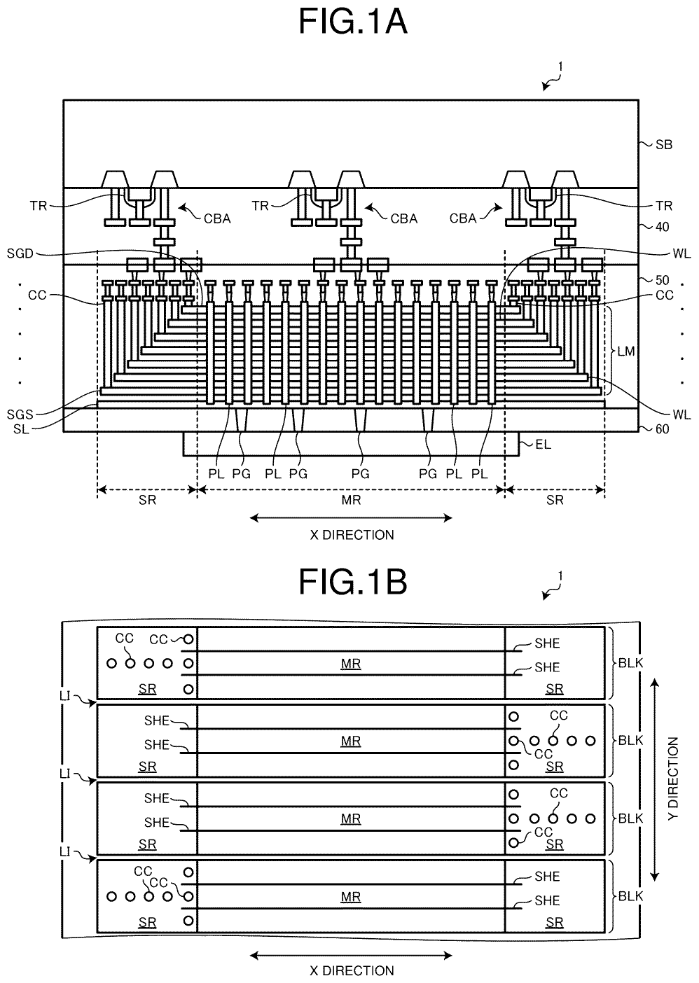

FIGS. 1A and 1B are diagrams illustrating a schematic configuration example of a semiconductor device 1 according to the embodiment. More specifically, FIG. 1A is a cross-sectional view along the X direction of the semiconductor device 1, and FIG. 1B is a schematic plan view illustrating a layout of the semiconductor device 1.

In FIG. 1A, however, hatching is omitted for ease of viewing the drawing. In addition, in FIG. 1A, configurations that do not necessarily exist in the same cross-section are illustrated, and some upper layer wiring and the like are omitted.

In the present specification, both the X direction and the Y direction are directions along the direction of the plane of a word line WL, and the X direction and the Y direction are orthogonal to each other. The electrical draw-out direction of the word line WL is sometimes referred to as a first direction, and the first direction is a direction along the X direction. The direction intersecting the first direction is sometimes referred to as a second direction, and the second direction is a direction along the Y direction. However, since the semiconductor device 1 may include manufacturing errors, the first direction and the second direction are not necessarily orthogonal to each other.

As illustrated in FIG. 1A, the semiconductor device 1 includes a semiconductor substrate SB provided with an electrode film EL, a source line SL, one or more selection gate lines SGS, a plurality of word lines WL, one or more selection gate lines SGD, and a peripheral circuit CBA in this order from the lower side of the drawing.

On the electrode film EL, the source line SL is disposed via an insulating layer 60. A plurality of plugs PG is disposed in the insulating layer 60, and the source line SL and the electrode film EL are electrically connected via the plugs PG. Although not illustrated, an electrode pad for supplying power and a signal to the semiconductor device 1 from the outside is provided in the same layer as the electrode film EL. On the source line SL, the selection gate line SGS, the plurality of word lines WL, and the selection gate line SGD are stacked in this order.

As illustrated in FIGS. 1A and 1B, a memory region MR is disposed in the central portion of the plurality of word lines WL and the like in the X direction, and staircase regions SR are respectively disposed in both end portions of the plurality of word lines WL and the like in the X direction. The memory region MR and the staircase region SR are divided into a plurality of regions by a plurality of plate-like contacts LI penetrating the plurality of word lines WL and the like and extending in a direction along the X direction.

Note that a region that is disposed between the plate-like contacts LI adjacent to each other in the Y direction and includes the memory region MR and the staircase region SR is referred to as a block region BLK. As will be described below, the memory region MR includes a plurality of memory cells for holding data in a nonvolatile manner, and the above-described block region BLK serves as a unit for erasing the data.

In addition, a plurality of separation layers SHE penetrating the selection gate line SGD and extending in a direction along the X direction is disposed between the plate-like contacts LI adjacent to each other in the Y direction. The plurality of separation layers SHE extends in a direction along the X direction over the entirety of memory region MR and reaches a part of the staircase region SR at both end portions in the X direction.

In the memory region MR, a plurality of pillars PL is disposed which penetrates the word lines WL and the selection gate lines SGD and SGS in the stacking direction thereof. The lower end of the pillar PL reaches the source line SL. A plurality of memory cells is formed at the intersection of the pillar PL and the word line WL. Thus, the semiconductor device 1 is configured as a three-dimensional nonvolatile memory in which memory cells are three-dimensionally arranged in the memory region MR, for example.

In the staircase region SR, the plurality of word lines WL and the selection gate lines SGD and SGS are processed into a staircase shape and terminated. At this point, as the distance from the memory region MR in the X direction increases, the plurality of word lines WL and the selection gate lines SGD and SGS, which constitute a terrace portion, move from the upper layer side to the lower layer side, so that the height position of the terrace portion decreases toward the source line SL side.

Note that, in the present specification, the direction in which the terrace surfaces of the plurality of word lines WL and the selection gate lines SGD and SGS face is defined as the upper side of the semiconductor device 1.

The above-described separation layer SHE extends from the memory region MR to a portion of the staircase region SR where the selection gate line SGD is processed into a staircase shape. Thus, in one block region BLK, the selection gate line SGD is separated into a plurality of regions. In other words, the separation layer SHE penetrates portions above the plurality of word lines WL, so that these upper layer portions are partitioned into the patterns of the plurality of selection gate lines SGD.

Contacts CC connected to the word line WL and the selection gate lines SGD and SGS of each layer are respectively disposed in a terrace portion of each stage constituted by the plurality of word lines WL and the selection gate lines SGD and SGS. In the word line WL and the selection gate line SGS, one contact CC is connected to each layer. In the selection gate line SGD, one contact CC is connected to each section separated by the separation layer SHE per layer.

Here, in one block region BLK, a plurality of contacts CC is disposed on one side of the staircase regions SR on both sides in the X direction. When viewed from one side in the X direction, the plurality of contacts CC is disposed for every two block regions BLK, for example.

That is, in the example of FIG. 1B, in the block region BLK at the uppermost part of the drawing, the plurality of contacts CC is disposed in, for example, the staircase region SR on the left side of the drawing among the staircase regions SR at both end portions in the X direction. In addition, in the block regions BLK one region below and two regions below the block region BLK described above, the plurality of contacts CC is disposed in the staircase region SR on the right side of the drawing among the staircase regions SR at both end portions in the X direction. Further, in the block region BLK at the lowermost part of the drawing, the plurality of contacts CC is disposed in the staircase region SR on the left side of the drawing.

Therefore, each of the contacts CC in the staircase regions SR at both end portions in the X direction illustrated in FIG. 1A belongs to a different block region BLK, and is not actually located in the same cross-section.

The word lines WL and the like stacked in multiple layers are individually drawn out by these contacts CC. More specifically, from these contacts CC, a write voltage, a read voltage, and the like are applied to the memory cell included in the memory region MR in the central portion of the plurality of word lines WL via the word line WL at the same height position as the memory cell.

The plurality of word lines WL, the selection gate lines SGD and SGS, the pillars PL, and the contacts CC are covered with an insulating layer 50. The insulating layer 50 also extends around these configurations including the plurality of word lines WL and the like.

The semiconductor substrate SB above the insulating layer 50 covering the above configuration is, for example, a silicon substrate or the like. The peripheral circuit CBA including a transistor TR, wiring, and the like is disposed on the surface of the semiconductor substrate SB. Various voltages applied from the contacts CC to the memory cells are controlled by the peripheral circuit CBA electrically connected to these contacts CC. Thus, the peripheral circuit CBA controls the electrical operation of the memory cell.

The peripheral circuit CBA is covered with an insulating layer 40, and the insulating layer 40 and the insulating layer 50 covering the plurality of word lines WL and the like are bonded to each other, whereby the semiconductor device 1 including the configuration of the plurality of word lines WL, the selection gate lines SGD and SGS, the pillars PL, the contacts CC, and the like, and the peripheral circuit CBA is configured.

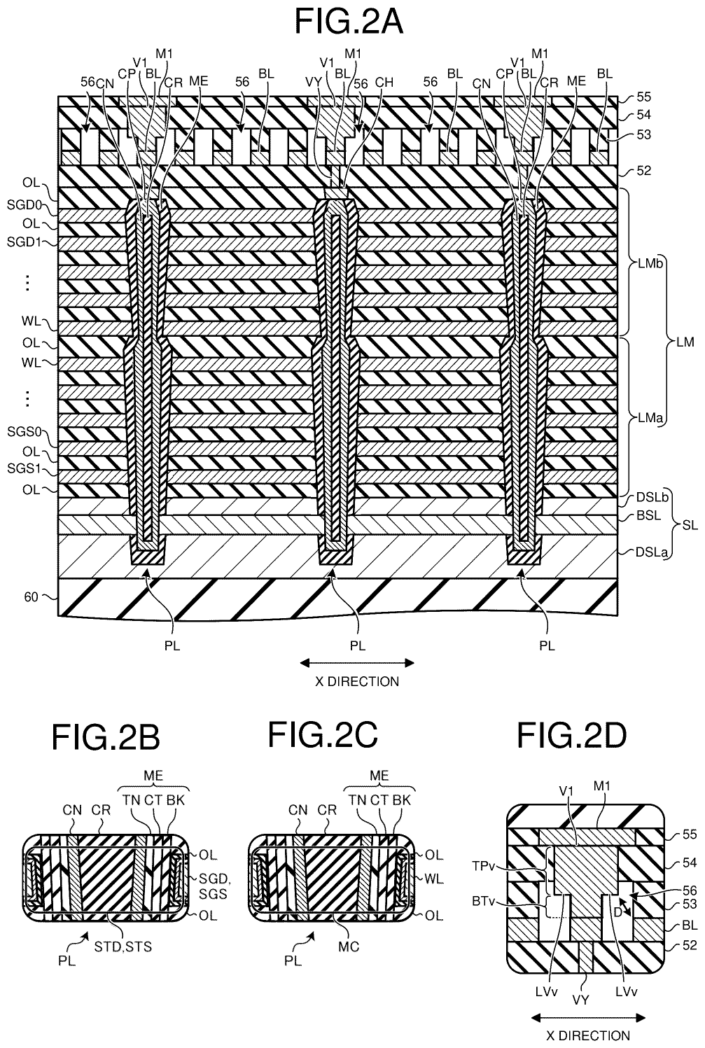

A detailed configuration example of the semiconductor device 1 will now be described with reference to FIGS. 2A to 2D. FIGS. 2A to 2D are cross-sectional views illustrating an example of the configuration of the semiconductor device 1 according to the embodiment.

More specifically, FIG. 2A is a cross-sectional view along the X direction in the memory region MR of the semiconductor device 1. In FIG. 2A, structures below the insulating layer 60 and above an insulating layer 53 to be described below are omitted.

FIG. 2B is an enlarged cross-sectional view of the pillar PL at the height position of the selection gate lines SGD and SGS. FIG. 2C is an enlarged cross-sectional view of the pillar PL at the height position of the word line WL. FIG. 2D is an enlarged cross-sectional view along the X direction illustrating a connection state between a bit line BL and an upper layer wiring M1.

As illustrated in FIG. 2A, the source line SL has a multilayer structure in which, for example, a lower source line DSLa, an intermediate source line BSL, and an upper source line DSLb are stacked in this order on the insulating layer 60. The lower source line DSLa, the intermediate source line BSL, and the upper source line DSLb are, for example, polysilicon layers or the like. Among the source lines, at least the intermediate source line BSL may be a conductive polysilicon layer or the like in which impurities are diffused.

Note that the source line SL is connected to the peripheral circuit CBA via the electrode film EL by a through contact, which is not illustrated, extending from the electrode film EL to the peripheral circuit CBA within the above-described insulating layer 50 outside a stacked body LM.

On the source line SL, the stacked body LM is disposed. The stacked body LM includes stacked bodies LMa and LMb in which the plurality of word lines WL and a plurality of insulating layers OL are alternately stacked one by one.

The stacked body LMa is disposed above the source line SL. In a further lower layer of the lowermost word line WL of the stacked body LMa, a plurality of selection gate lines SGS0 and SGS1 is disposed in this order from the upper layer side of the stacked body LMa via the insulating layer OL. The stacked body LMb is disposed on the stacked body LMa. In a further upper layer of the uppermost word line WL of the stacked body LMb, a plurality of selection gate lines SGD0 and SGD1 is disposed in this order from the upper layer side of the stacked body LMb via the insulating layer OL.

However, the number of stacks of the word lines WL and the selection gate lines SGD and SGS in the stacked body LM is any number. The word lines WL and the selection gate lines SGD and SGS are, for example, a tungsten layer or a molybdenum layer. The insulating layer OL is, for example, a silicon oxide layer.

The upper surface of the stacked body LM is covered with insulating layers 52 to 55 in this order. The insulating layers 52 to 55 each constitutes a portion of the insulating layer 50 of FIG. 1A.

In the memory region MR, a plurality of pillars PL penetrating the stacked body LM, the upper source line DSLb, and the intermediate source line BSL and reaching the lower source line DSLa is dispersedly disposed.

The plurality of pillars PL is arranged, for example, in a staggered manner when viewed from the stacking direction of the stacked body LM. Each of the pillars PL has a cross-sectional shape in a direction along the layer direction of the stacked body LM, that is, in a direction along the XY plane, such as a circular shape, an elliptical shape, or an oblong shape (oval shape).

In addition, the pillars PL each has a tapered shape in which the diameter and the cross-sectional area decrease from the upper layer side toward the lower layer side in the portion penetrating the stacked body LMa and the portion penetrating the stacked body LMb.

Alternatively, the pillars PL each has a bowing shape in which the diameter and the cross-sectional area are maximized, for example, at a predetermined position between the upper layer side and the lower layer side in the portion penetrating the stacked body LMa and the portion penetrating the stacked body LMb.

Each of the plurality of pillars PL has a memory layer ME extending within the stacked body LM in the stacking direction, a channel layer CN penetrating within the stacked body LM and connected to the intermediate source line BSL, a cap layer CP covering the upper surface of the channel layer CN, and a core layer CR serving as a core material of the pillar PL.

More specifically, the channel layer CN is in direct contact with the intermediate source line BSL at the depth position of the intermediate source line BSL. That is, the memory layer ME is disposed on the side surface of the pillar PL except for the depth position of the intermediate source line BSL. The memory layer ME is also disposed on the bottom surface of the pillar PL that reaches the depth of the lower source line DSLa.

Thus, the channel layer CN is in contact with the intermediate source line BSL on a side surface thereof, and is further electrically connected to the entirety of source line SL via the intermediate source line BSL.

The cap layer CP is disposed at the upper end portion of the pillar PL so as to cover at least the upper end portion of the channel layer CN, and is connected to the channel layer CN. Further, the cap layer CP is connected to the bit line BL disposed further above the insulating layer 52 via a plug CH disposed in the uppermost insulating layer OL of the stacked body LM and a plug VY disposed in the insulating layer 52. The bit line BL extends above the stacked body LM in a direction along the Y direction so as to intersect the draw-out direction of the word line WL.

As illustrated in FIGS. 2B and 2C, the memory layer ME has a stacked structure including a block insulating layer BK, a charge storage layer CT, and a tunnel insulating layer TN in order from the outer peripheral side of the pillar PL.

The block insulating layer BK and the tunnel insulating layer TN of the memory layer ME, and the core layer CR are, for example, silicon oxide layers. The charge storage layer CT is, for example, a silicon nitride layer. The channel layer CN and the cap layer CP are, for example, semiconductor layers such as polysilicon layers or amorphous silicon layers.

As illustrated in FIG. 2C, with the above-described configuration, the memory cells MC are respectively formed in the portions of the side surfaces of the pillar PL facing the individual word lines WL. A predetermined voltage is applied from the word line WL, so that data is written to and read from the memory cell MC.

As illustrated in FIG. 2B, selection gates STD are respectively formed in portions where the side surfaces of the pillar PL face the selection gate lines SGD0 and SGD1. In addition, selection gates STS are respectively formed in portions where the side surfaces of the pillar PL face the selection gate lines SGS0 and SGS1 in a layer lower than the word lines WL.

A predetermined voltage is respectively applied from the selection gate lines SGD and SGS, so that the selection gates STD and STS are turned on or off, and the memory cell MC of the pillar PL to which the selection gates STD and STS belong can be set to a selected state or an unselected state.

As illustrated in FIG. 2A, the plurality of bit lines BL extends in a direction along the Y direction on the insulating layer 52 covering the stacked body LM at a predetermined distance from each other in the X direction.

The plurality of pillars PL arranged in the X direction is connected to every predetermined number of bit lines BL among the plurality of bit lines BL arranged at predetermined intervals in the X direction via the above-described plugs CH and VY. For example, in the example of FIG. 2A, the plurality of pillars PL is respectively connected to every fifth bit line BL. The other bit lines BL are connected to pillars PL different from the pillars PL illustrated in FIG. 2A via plugs CH and VY, which are not illustrated in FIG. 2B, at positions different from the cross-section illustrated in FIG. 2A.

The plurality of bit lines BL is covered with the insulating layer 53. Air gap layers 56 are respectively disposed between the plurality of bit lines BL. These air gap layers 56 protrude to the height position of the upper surface of the insulating layer 53, and the insulating layer 53 is also divided into a plurality of linear shapes extending in the direction along the Y direction.

The upper layer wiring M1 disposed in the insulating layer 55 is connected to the plurality of bit lines BL via a via V1 extending by penetrating the insulating layers 54 and 53.

As illustrated in FIG. 2D, the via V1 includes an upper via TPv having a diameter larger than the width of the bit line BL in the direction along the X direction, and a lower via BTv having a diameter smaller than the diameter of the upper via TPv. More specifically, the diameter of the lower via BTv is substantially equal to the width of the bit line BL in the direction along the X direction.

The upper via TPv is connected to the upper layer wiring M1 at an upper end portion thereof, and extends downward in the insulating layer 54. The lower via BTv extends downward in the insulating layer 53 from the lower end portion of the upper via TPV, and is connected to the bit line BL at the lower end portion.

The upper via TPv and the lower via BTv are connected to each other at a height position between the height position of the upper surface of the insulating layer 53 and the height position of the upper surface of the bit line BL. Thus, the via V1 has a step LVv protruding toward the air gap layers 56 on both sides in the X direction at the connection portion between the upper via TPv and the lower via BTV.

Note that the upper via TPv and the lower via BTV are preferably connected to each other at a height position above the upper surface of the bit line BL by a predetermined distance. Thus, the distance D between the most protruding portion of the step LVv of the via V1 and the bit line BL adjacent in the X direction to the bit line BL to which the via V1 is connected can be increased, and the capacitance between the via V1 and the adjacent bit line BL can be reduced.

In addition, the via V1 and the adjacent bit line BL are separated by the air gap layer 56 having a low dielectric constant. The dielectric constant of the air gap layer 56 is, for example, 1. Thus, the capacitance between the via V1 and the bit line BL can be further reduced, and the breakdown voltage can be ensured.

Note that the distance D between the protruding portion of the step LVv of the via V1 and the adjacent bit line BL is preferably larger than or equal to the distance between the plurality of bit lines BL, for example.

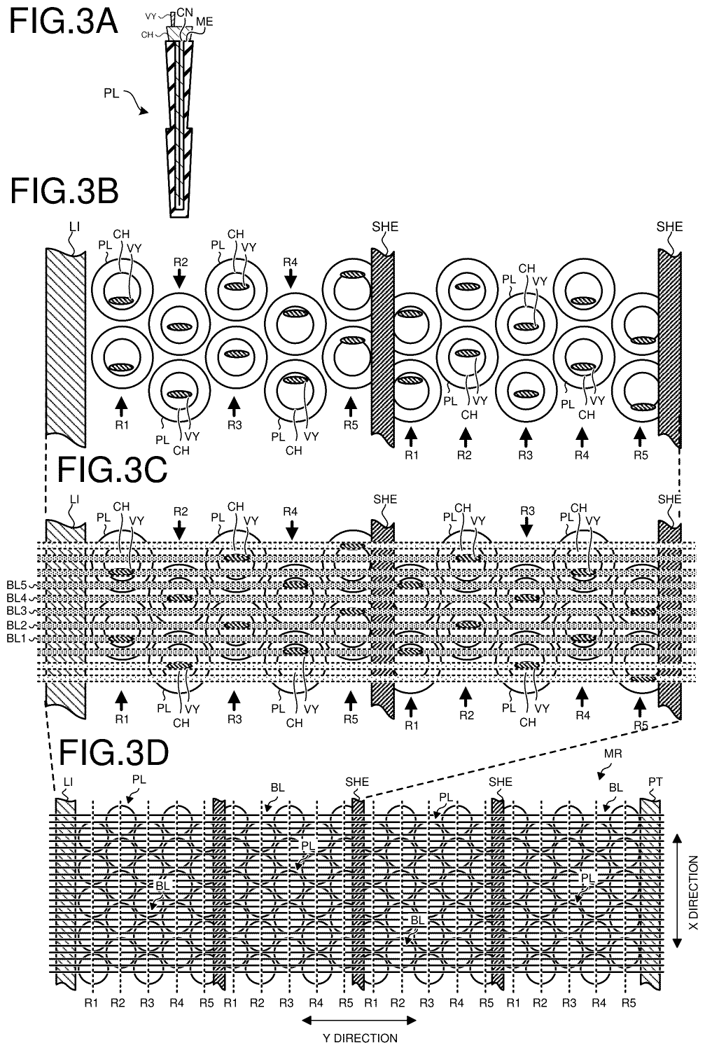

A detailed example of a connection mode between the pillar PL and the bit line BL will now be described with reference to FIGS. 3A to 3D. FIGS. 3A to 3D are schematic diagrams illustrating an example of layout of various configurations in the memory region MR of the semiconductor device 1 according to the embodiment.

More specifically, FIG. 3A is a schematic diagram illustrating an example of a connection mode between the pillar PL and the plugs CH and VY. FIGS. 3B and 3C are partially enlarged views of the memory region MR, FIG. 3B is a view in which the bit line BL is omitted, and FIG. 3C is a view in which the bit line BL is illustrated. FIG. 3D is a schematic top view illustrating a part of the memory region MR.

As illustrated in FIG. 3D and as described above, the memory region MR between the plate-like contacts LI adjacent to each other in the Y direction is separated into a plurality of sections by the plurality of separation layers SHE extending in a direction along the X direction.

That is, the plate-like contacts LI are arranged side by side in the Y direction and extend in a direction along the stacking direction of the stacked body LM and the X direction. More specifically, the plate-like contact LI penetrates the stacked body LM and the upper source line DSLb and reaches the intermediate source line BSL (see FIG. 2A).

On the other hand, the plurality of separation layers SHE extends in a direction along the X direction in a region between the plate-like contacts LI adjacent to each other in the Y direction by penetrating the upper layer portion of the stacked body LMb. More specifically, these separation layers SHE penetrate the selection gate lines SGD0 and SGD1 (see FIG. 2A) and reach the insulating layer OL immediately below the selection gate line SGD1.

In other words, these separation layers SHE penetrating the upper layer portion of the stacked body LMb extend in the X direction in the memory region MR and a portion of the staircase region SR between the plate-like contacts LI, whereby the upper layer portion of the stacked body LMb is partitioned into the above-described selection gate lines SGD0 and SGD1.

The plurality of pillars PL is arranged in a plurality of columns extending in the X direction between the plate-like contact LI and the separation layer SHE, which are adjacent to each other in the Y direction, and between the separation layers SHE adjacent to each other in the Y direction. In the column of FIG. 3D, the arrangement of the plurality of pillars PL is five columns of columns R1 to R5. However, one end side in the Y direction of the pillars PL belonging to the columns R1 and R5 adjacent to the separation layer SHE overlaps the separation layer SHE when viewed from the stacking direction of the stacked body LM. The separation layer SHE is, for example, an insulating layer or the like, and does not affect the electrical characteristics of the pillar PL even when the separation layer is in contact with the pillar PL.

In the arrangement of the pillars PL, the pillars PL belonging to the columns R1 and R2 adjacent to each other, the columns R2 and R3 adjacent to each other, the columns R3 and R4 adjacent to each other, and the columns R4 and R5 adjacent to each other are disposed by shifting the positions in the Y direction so as not to overlap each other in the Y direction. On the other hand, the pillars PL belonging to the columns R1, R3, and R5 that separate the adjacent columns from each other and the pillars PL belonging to the columns R2 and R4 that separate the adjacent columns from each other are disposed such that the positions of the columns in the Y direction coincide with each other.

Thus, the plurality of pillars PL is arranged in a staggered manner when viewed from the stacking direction of the stacked body LM, for example. More preferably, the plurality of pillars PL is disposed to have a substantially equal pitch with respect to each other.

Note that, as described above, by disposing the plurality of pillars PL so as to allow interference between some of the pillars PL and the separation layer SHE, a periodic arrangement such as a staggered arrangement of the pillars PL can be maintained, for example. Thus, when the plurality of pillars PL is formed with high density, the processing accuracy of the pillars PL can be improved.

To describe the pillar PL overlapping the separation layer SHE in more detail, one end side in the Y direction of the pillar PL disposed in the region between the plate-like contact LI and the separation layer SHE and belonging to the column R1 or the column R5 overlaps the separation layer SHE at the height of the selection gate line SGD, and the overlapping portion is chipped. In addition, the selection gate line SGD surrounding the pillar PL of the column R1 or the column R5 overlaps the separation layer SHE, and the overlapping portion is chipped.

However, the selection transistor STD formed at the intersection of the pillar PL and the selection gate line SGD is adjusted to function as the selection transistor STD also in the pillar PL of the column R1 or the column R5. In addition, since the separation layer SHE does not reach the height of the word line WL, chipping does not occur in the pillar PL of the column R1 or the column R5, and chipping also does not occur in the word line WL. Therefore, the memory cell MC formed at the intersection of the pillar of the column R1 or the column R5 and the word line WL functions similarly to the memory cell MC belonging to the pillars PL of the other columns.

Similarly, one end side in the Y direction of the pillar PL disposed in the region between the two separation layers SHE and belonging to the columns R1 and R5 overlaps the separation layer SHE at the height of the selection gate line SGD, and the overlapping portion is chipped. In addition, the selection gate lines SGD surrounding the pillars PL of the columns R1 and R5 overlap the separation layer SHE, and the overlapping portions are chipped.

However, the selection transistor STD formed at the intersection of the pillar PL and the selection gate line SGD is adjusted to function as the selection transistor STD also in the pillars PL of the column R1 and the column R5. Since the separation layer SHE does not reach the height of the word line WL, chipping does not occur in the pillars PL of the columns R1 and R5, and chipping also does not occur in the word line WL. Therefore, the memory cell MC formed at the intersection of the pillars of the column R1 and the column R5 and the word line WL functions similarly to the memory cell MC belonging to the pillars PL of the other columns.

As illustrated in FIG. 3A and as described above, the plugs CH and VY are disposed in this order from the pillar PL side at the upper end portion of the pillar PL, and the individual pillars PL are connected to the bit line BL above the pillar via the plugs CH and VY.

That is, above these pillars PL, the plurality of bit lines BL respectively extending in the Y direction is disposed, for example, to be spaced apart from each other by a predetermined distance in the X direction. More preferably, the plurality of bit lines BL is disposed to be spaced apart from each other in the X direction at substantially equal intervals.

The individual pillar PL are electrically connected to any one of the bit lines BL. At this point, in order to enable the memory cells MC belonging to the individual pillars PL to be individually driven, the pillars PL disposed between the plate-like contact LI and the separation layer SHE, which are adjacent to each other in the Y direction, and between the separation layers SHE adjacent to each other in the Y direction are respectively connected to different bit lines BL. FIG. 3C illustrates a configuration of the pillar PL for realizing such a connection mode.

As illustrated in FIG. 3B, the pillar PL has, for example, a circular shape when viewed from the stacking direction of the stacked body LM. However, the pillar PL may have another shape such as an oval shape or an elliptical shape.

The plug CH at the upper end portion of the pillar PL has, for example, an upper surface shape similar to that of the pillar PL. In the example of FIG. 3B, as with the circular pillar PL, the plug CH also has a circular shape when viewed from the stacking direction of the stacked body LM. However, the plug CH may have another shape such as an oval shape or an elliptical shape.

When viewed from the stacking direction of the stacked body LM, the outer shape of the plug CH is smaller than the outer shape of the pillar PL, and the plug is disposed so as to fall within the range of the upper surface of the pillar PL. In addition, the center point of the plug CH when viewed from the stacking direction of the stacked body LM substantially coincides with the center point of the corresponding pillar PL.

On the other hand, the plug VY disposed on the upper surface of the plug CH has, for example, an elliptical shape having a longitudinal direction in a direction along the Y direction. That is, the plug VY extends in the direction in which the bit line BL extends.

In addition, the center point of the plug VY when viewed from the stacking direction of the stacked body LM substantially coincides with the center point of the corresponding pillar PL and plug CH in the Y direction and deviates in the X direction. At this point, the amount of deviation between the center point of the plug VY and the center point of the corresponding pillar PL and plug CH is different for the individual pillars PL such that the pillars PL disposed between the plate-like contact LI and the separation layer SHE, which are adjacent to each other in the Y direction, and between the separation layers SHE adjacent to each other in the Y direction are respectively connected to different bit lines BL.

As illustrated in FIG. 3C, when the bit lines BL are superimposed on FIG. 3B, it can be seen that, with the above configuration, the pillars PL disposed between the plate-like contact LI and the separation layer SHE, which are adjacent to each other in the Y direction, and between the separation layers SHE adjacent to each other in the Y direction are respectively connected to different bit lines BL.

More specifically, the position of the individual plugs VY in the X direction is determined in accordance with the position of the bit line BL to be connected among the plurality of bit lines BL in the X direction. Therefore, as described above, the amount of deviation in the X direction between the center point of the plug VY and the center point of the corresponding pillar PL and plug CH individually changes, and due to such a displacement of the center point, the pillars PL disposed between the plate-like contact LI and the separation layer SHE and between the separation layers SHE can be individually connected to different bit lines BL.

That is, in the example illustrated in FIG. 3C, between the plate-like contact LI and the separation layer SHE, which are adjacent to each other in the Y direction, a predetermined pillar PL belonging to the column R1 is connected to the bit line BL1 via the plugs CH and VY. The pillar PL which is in close proximity to the pillar PL of the above-described column R1 connected to the bit line BL1 and belongs to the column R2 is connected to the bit line BL4 via the plugs CH and VY. The pillar PL which is in close proximity to the pillar PL of the above-described column R2 connected to the bit line BL4 and belongs to the column R3 is connected to the bit line BL2 via the plugs CH and VY. The pillar PL which is in close proximity to the pillar PL of the above-described column R3 connected to the bit line BL2 and belongs to the column R4 is connected to the bit line BL5 via the plugs CH and VY. The pillar PL which is in close proximity to the pillar PL of the above-described column R4 connected to the bit line BL5 and belongs to the column R5 is connected to the bit line BL3 via the plugs CH and VY.

In the example illustrated in FIG. 3C, between the separation layers SHE adjacent to each other in the Y direction, a predetermined pillar PL belonging to the column R1 is connected to the bit line BL5 via the plugs CH and VY. The pillar PL which is in close proximity to the pillar PL of the above-described column R1 connected to the bit line BL5 and belongs to the column R2 is connected to the bit line BL2 via the plugs CH and VY. The pillar PL which is in close proximity to the pillar PL of the above-described column R2 connected to the bit line BL2 and belongs to the column R3 is connected to the bit line BL4 via the plugs CH and VY. The pillar PL which is in close proximity to the pillar PL of the above-described column R3 connected to the bit line BL4 and belongs to the column R4 is connected to the bit line BL1 via the plugs CH and VY. The pillar PL which is in close proximity to the pillar PL of the above-described column R4 connected to the bit line BL1 and belongs to the column R5 is connected to the bit line BL3 via the plugs CH and VY.

As described above, the plurality of bit lines BL is connected to any pillars PL of the columns R1 to R5 in five cycles. In other words, among the arrangements of the plurality of pillars PL, the pillars PL belonging to the same column as any one of the columns R1 to R5 are connected to every fifth bit line BL, which is the same number as the number of the arranged pillars PL, among the plurality of bit lines BL arranged in the Y direction.

As described above, in order to connect the plurality of bit lines BL to each of the plurality of pillars PL disposed in high density in a staggered manner, the plurality of bit lines BL is also disposed at a narrow pitch by reducing the separation distance in the X direction.

### (Method of Manufacturing Semiconductor Device)

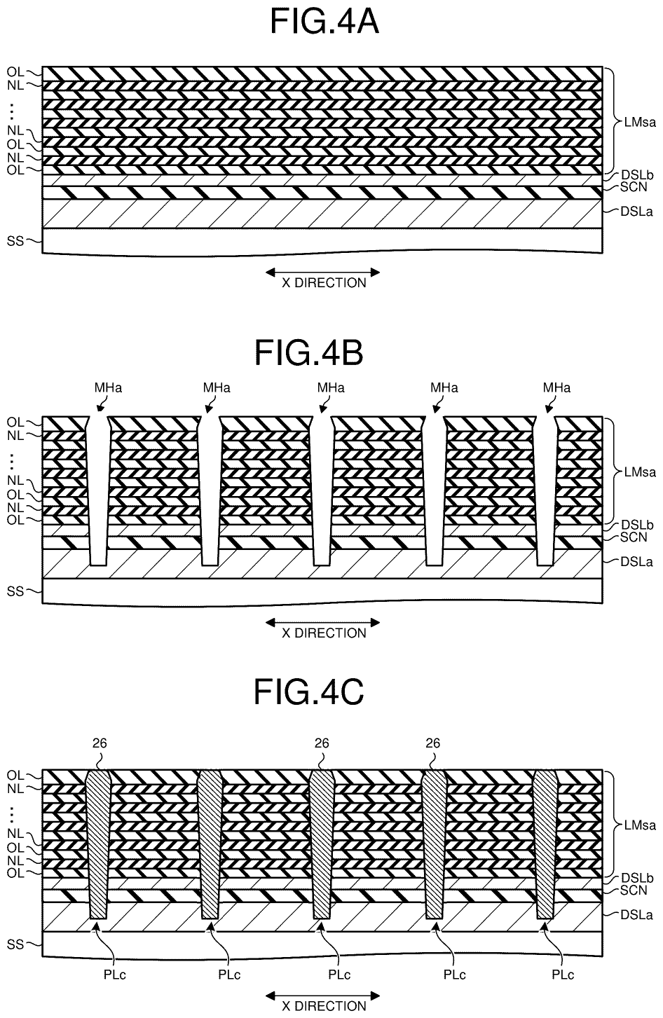

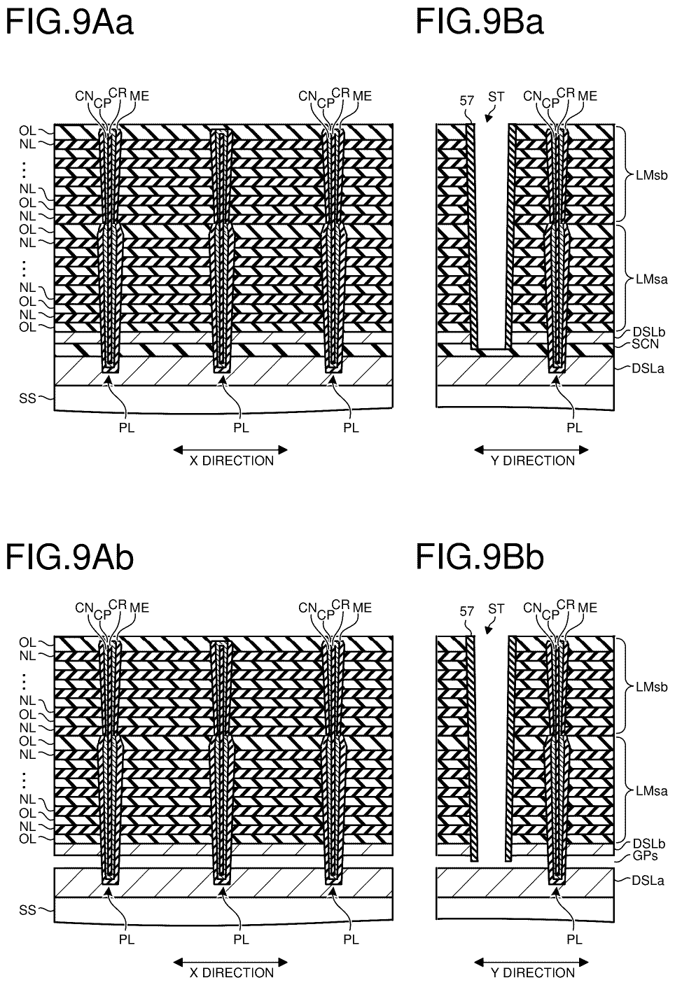

A method of manufacturing the semiconductor device 1 according to the embodiment will now be described with reference to FIGS. 4A to 16D. FIGS. 4A to 16D are diagrams sequentially illustrating a part of the procedure of the method of manufacturing the semiconductor device 1 according to the embodiment. FIGS. 4A to 16D, excluding FIGS. 9Aa to 11Bb, 14B, and 16A, illustrate cross-sections along the X direction of a region that later becomes the memory region MR.

As illustrated in FIG. 4A, the lower source line DSLa, an intermediate sacrificial layer SCN, and the upper source line DSLb are formed in this order on a support substrate SS.

As the support substrate SS, a semiconductor substrate such as a silicon substrate, an insulating substrate such as a ceramic substrate, a conductive substrate, or the like can be used. The above-described insulating layer 60 (see FIG. 2A and the like) may be formed on the upper surface side of the support substrate SS. The intermediate sacrificial layer SCN is, for example, a silicon nitride layer or the like, and is a layer that is later replaced with a polysilicon layer or the like to become the intermediate source line BSL.

On the upper source line DSLb, a stacked body LMsa is formed in which a plurality of insulating layers NL and the plurality of insulating layers OL are alternately stacked one by one. The insulating layer NL is, for example, a silicon nitride layer or the like, and functions as a sacrificial layer that is later replaced with a conductive material to become the word line WL or the selection gate line SGS.

Thereafter, although not illustrated, the insulating layer NL and the insulating layer OL are processed into a staircase shape in a partial region of the stacked body LMsa. Such processing can be performed by repeating slimming of a mask pattern such as a photoresist layer and etching of the insulating layer NL and the insulating layer OL of the stacked body LMsa a plurality of times.

That is, a mask pattern is formed on the upper surface of the stacked body LMsa, and the insulating layer NL and the insulating layer OL of the exposed portion are etched and removed one by one. In addition, the end portion of the mask pattern is retreated by a process using oxygen plasma or the like to newly expose the upper surface of the stacked body LMsa, and the insulating layer NL and the insulating layer OL are further etched and removed one by one. By repeating such a process a plurality of times, the stacked body LMsa having a staircase shape at both end portions in the X direction is formed.

Then, the staircase shape at both end portions in the X direction is covered with a part of the above-described insulating layer 50 (see FIG. 1A).

As illustrated in FIG. 4B, a plurality of memory holes MHa extending through the stacked body LMsa in the stacking direction is formed. The plurality of memory holes MHa penetrates the stacked body LMsa, the upper source line DSLb, and the intermediate sacrificial layer SCN, and reaches the lower source line DSLa. These memory holes MHa are portions that later become the lower structures of the pillars PL.

As illustrated in FIG. 4C, these memory holes MHa are filled with a sacrificial layer 26 such as an amorphous silicon layer or a CVD-carbon layer. Thus, pillars PLC are formed in which the plurality of memory holes MHa is filled with the sacrificial layer 26.

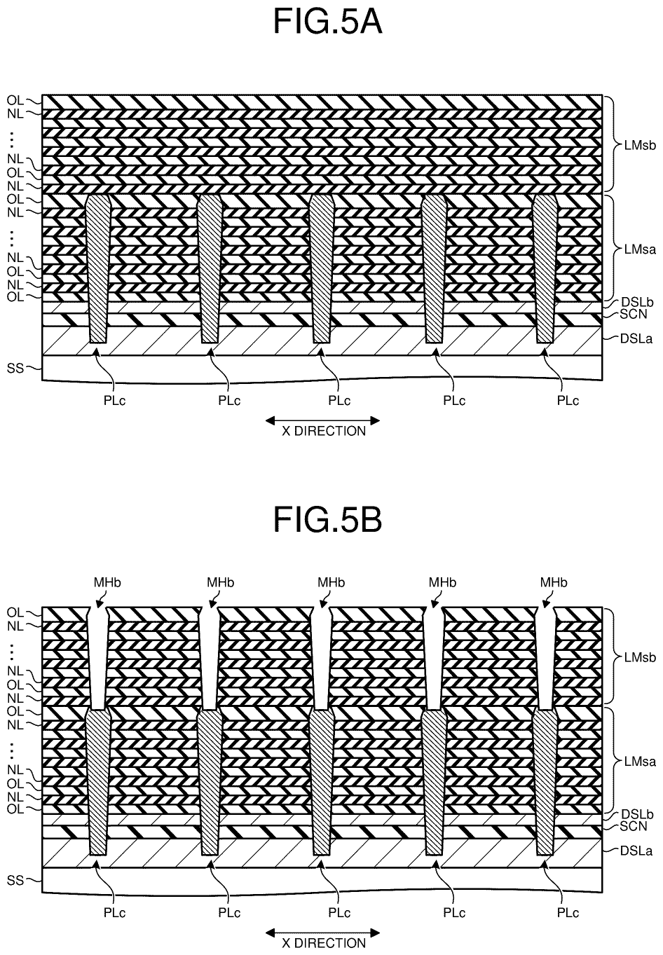

As illustrated in FIG. 5A, a stacked body LMsb is formed which covers the stacked body LMsa and in which the plurality of insulating layers NL and the plurality of insulating layers OL are alternately stacked one by one. The insulating layer NL of the stacked body LMsb functions as a sacrificial layer that is later replaced with a conductive layer to become the word line WL or the selection gate line SGD.

Thereafter, although not illustrated, the insulating layer NL and the insulating layer OL are processed into a staircase shape in a partial region of the stacked body LMsb. Such processing can be performed by repeating slimming of a mask pattern such as a photoresist layer and etching of the insulating layer NL and the insulating layer OL of the stacked body LMsb a plurality of times, as with the above-described process on the stacked body LMsa.

At this point, the uppermost step of the staircase portion formed in the stacked body LMsa and the lowermost step of the staircase portion formed in the stacked body LMsb are brought close to each other, and the staircase shape is formed so as to be continuously connected from the lower layer side of the stacked body LMsa to the upper layer side of the stacked body LMsb. Thus, the stacked bodies LMsa and LMsb are formed in which the staircase region SR having a staircase shape from the stacked body LMsa to the stacked body LMsb is formed at both end portions in the X direction.

Then, the staircase shape at both end portions in the X direction is further covered with a part of the above-described insulating layer 50 (see FIG. 1A).

As illustrated in FIG. 5B, a plurality of memory holes MHb is formed which penetrates the stacked body LMsb and is respectively connected to the plurality of pillars PLc formed in the stacked body LMsa. The memory hole MHb is a portion that later becomes an upper structure of the pillar PL.

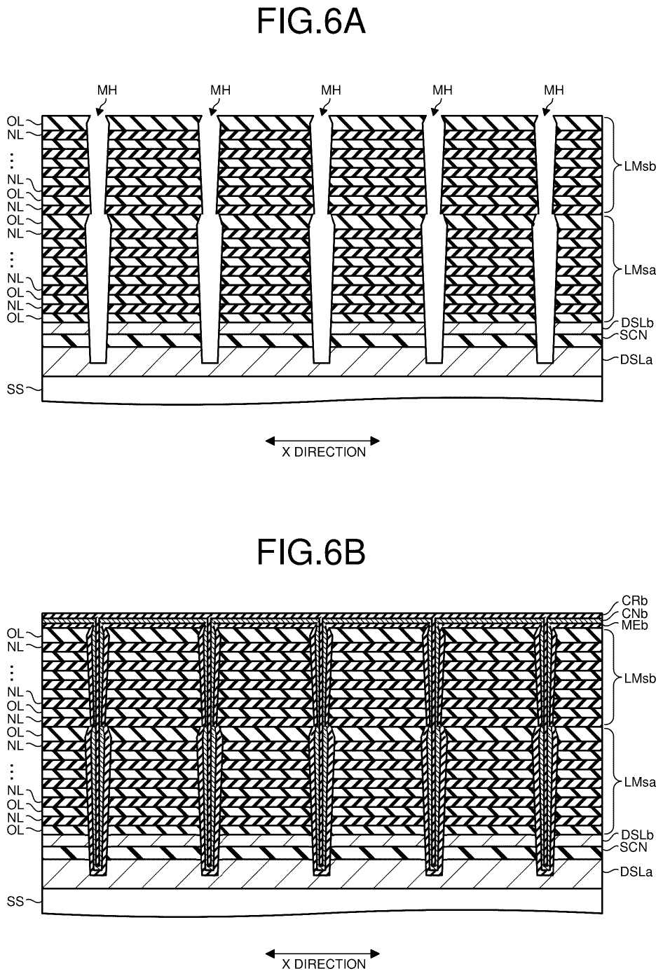

As illustrated in FIG. 6A, the sacrificial layer 26 is removed from the pillar PLc at the bottom of the memory hole MHb. Thus, the memory hole MHa is opened at the bottom of the plurality of memory holes MHb, respectively, and a plurality of memory holes MH is formed which penetrates the stacked bodies LMsb and LMsa, the upper source line DSLb, and the intermediate sacrificial layer SCN and reaches the lower source line DSLa.

Note that, in a case where the sacrificial layer 26 filled in the pillar PLc is a CVD-carbon layer or the like, the sacrificial layer 26 can be collectively removed from these pillars PLC when the mask pattern or the like used at the time of forming the memory hole MHb in FIG. 5B described above is removed by ashing or the like using oxygen plasma.

As illustrated in FIG. 6B, a memory layer MEb, a channel layer CNb, and a core layer CRb are formed in this order in the memory hole MH. Thus, the memory layer MEb and the channel layer CNb are formed on the side surface of the memory hole MH and the bottom surface where the lower source line DSLa is exposed, and the core layer CRb is filled in the central portion of the memory hole MH. The memory layer MEb, the channel layer CNb, and the core layer CRb are also formed in this order on the upper surface of the stacked body LMsb.

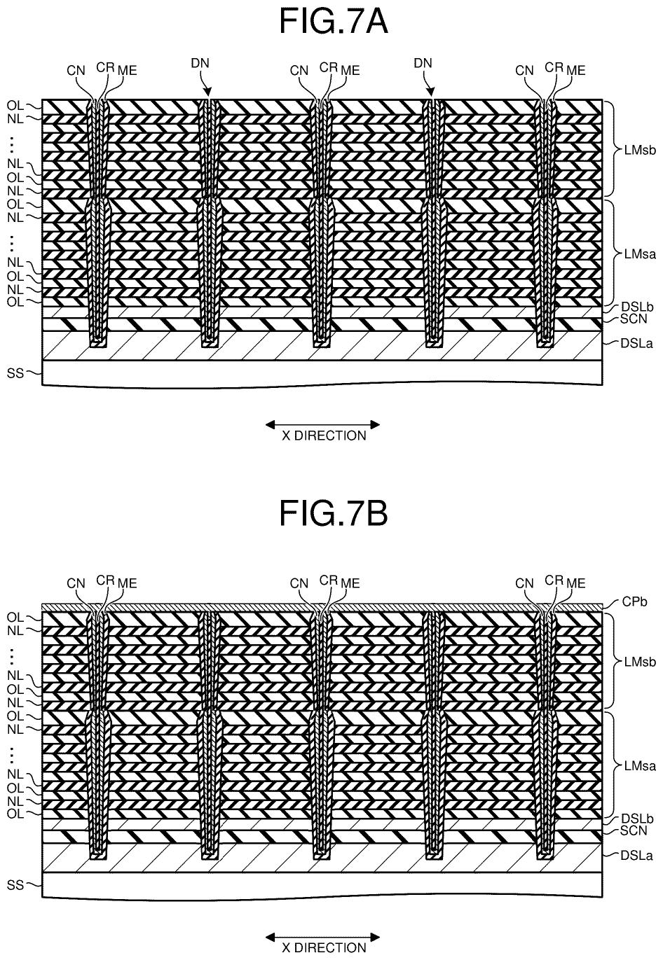

As illustrated in FIG. 7A, the core layer CRb, the channel layer CNb, and the memory layer MEb formed on the upper surface of the stacked body LMsb are etched back to form the core layer CR, the channel layer CN, and the memory layer ME which are individually separated in the memory hole MH. In addition, a depression DN is formed at the upper end portion of the core layer CR.

As illustrated in FIG. 7B, a cap layer CPb is formed in the depression DN at the upper end portion of the memory hole MH. The cap layer CPb is also formed on the upper surface of the stacked body LMsb.

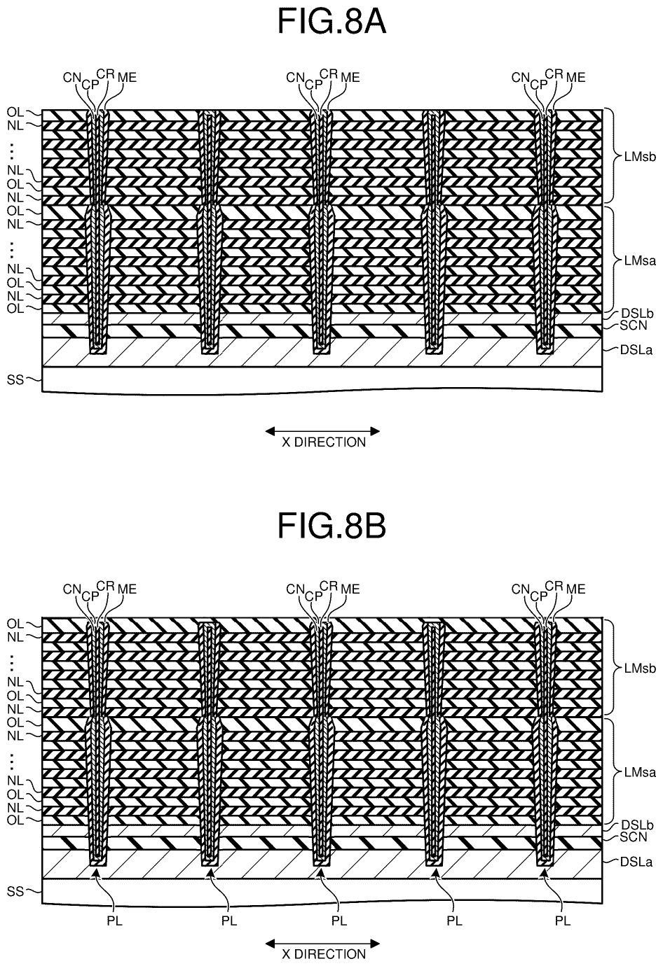

As illustrated in FIG. 8A, the cap layer CPb on the upper surface of the stacked body LMsb is removed together with a portion of the uppermost insulating layer OL of the stacked body LMsb by CMP or the like to form the cap layer CP disposed at the upper end portion of the memory hole MH.

As illustrated in FIG. 8B, the uppermost insulating layer OL of the stacked body LMsb, which has been thinned by CMP or the like, is added. Thus, the pillar PL in which the cap layer CP is buried in the uppermost insulating layer OL is formed. However, at this point, the memory layer ME covers the entire sidewall of the pillar PL, and a part of the side surface of the channel layer CN is not exposed from the memory layer ME.

In the following, FIGS. 9Aa to 11Bb also illustrate cross-sections along the Y direction as well as cross-sections along the X direction of a region that later becomes the memory region MR. More specifically, in FIGS. 9Aa to 11Bb, Aa and Ab are cross-sections along the X direction, and Ba and Bb are cross-sections along the Y direction.

As illustrated in FIG. 9Ba, a slit ST is formed which penetrates the stacked bodies LMsb and LMsa and the upper source line DSLb and reaches the intermediate sacrificial layer SCN. In addition, insulating layers 57 are formed on the sidewalls of the slit ST facing each other in the Y direction. The slit ST also extends within the stacked bodies LMsa and LMsb in a direction along the X direction.

As illustrated in FIGS. 9Ab and 9Bb, the intermediate sacrificial layer SCN sandwiched between the lower source line DSLa and the upper source line DSLb is removed by flowing a removing liquid of the intermediate sacrificial layer SCN, such as hot phosphoric acid, via the slit ST whose sidewalls are protected by the insulating layers 57.

Thus, a gap layer GPs is formed between lower source line DSLa and upper source line DSLb. In addition, a part of the memory layer ME in the outer peripheral portion of the pillar PL is exposed in the gap layer GPs. At this point, since the sidewalls of the slit ST are protected by the insulating layer 57, the insulating layer NL in the stacked bodies LMsa and LMsb is prevented from being removed.

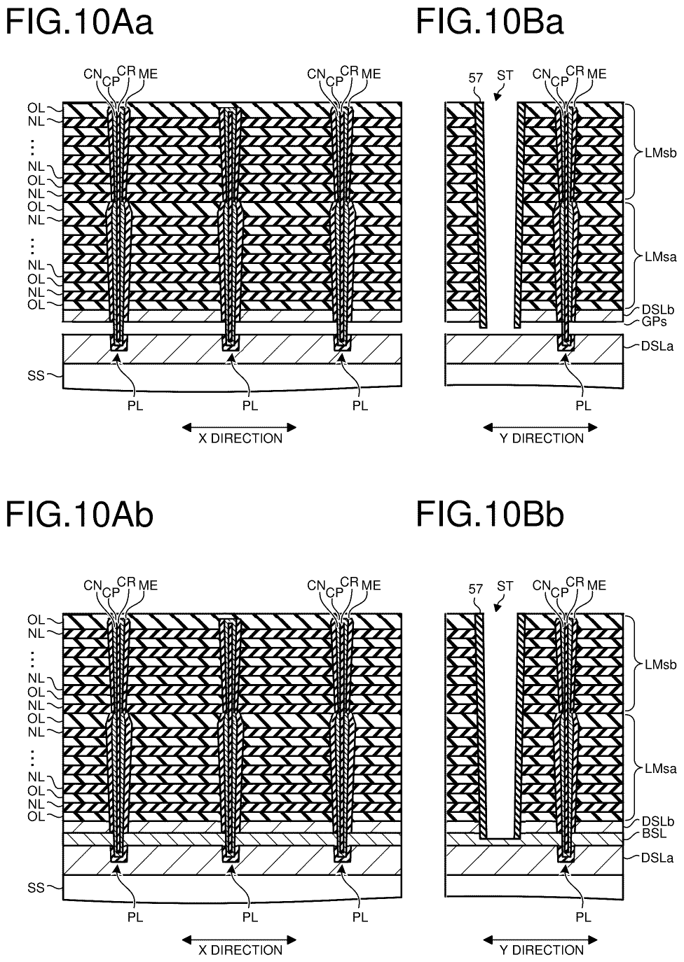

As illustrated in FIGS. 10Aa and 10Ba, the block insulating layer BK, the charge storage layer CT, and the tunnel insulating layer TN (see FIGS. 2B and 2C) of the memory layer ME exposed in the gap layer GPs are sequentially removed by appropriately flowing a chemical solution into the gap layer GPs via the slit ST. Thus, the memory layer ME is removed from a part of the sidewall of the pillar PL, and a part of the inner channel layer CN is exposed in the gap layer GPs.

As illustrated in FIGS. 10Ab and 10Bb, a raw material gas such as amorphous silicon is injected from the slit ST whose sidewalls are protected by insulating layers 57, and the gap layer GPs is filled with amorphous silicon or the like. In addition, the support substrate SS is heat-treated to polycrystallize the amorphous silicon filled in the gap layer GPs to form the intermediate source line BSL containing polysilicon or the like.

Thus, a part of the channel layer CN of the pillar PL is connected to the source line SL on a side surface thereof via the intermediate source line BSL. Then, the insulating layers 57 on the sidewalls of the slit ST are removed.

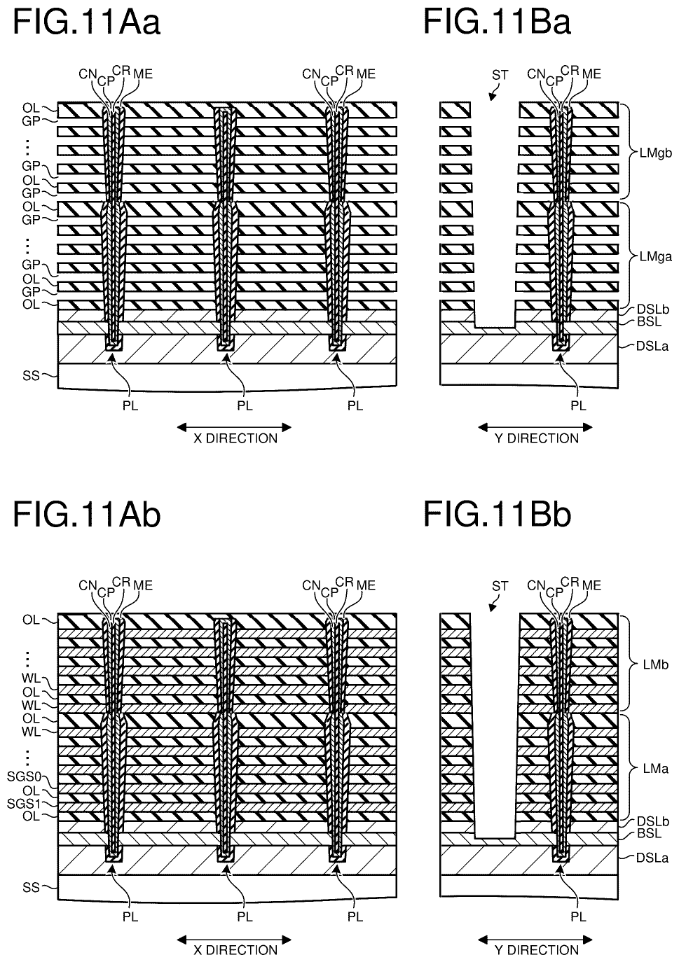

As illustrated in FIGS. 11Aa and 11Ba, the insulating layer NL of the stacked bodies LMsa and LMsb is removed by flowing a removing liquid of the insulating layer NL, such as hot phosphoric acid, into the stacked bodies LMsa and LMsb from the slit ST from which the insulating layer 57 is removed. Thus, the stacked bodies LMga and LMgb are formed which have a plurality of gap layers GP from which the insulating layer NL between the insulating layers OL is removed.

The stacked bodies LMga and LMgb including the plurality of gap layers GP have fragile structures. The plurality of pillars PL supports such fragile stacked bodies LMga and LMgb. Thus, the insulating layer OL remaining in the stacked bodies LMga and LMgb is prevented from being bent, and the stacked bodies LMga and LMgb are prevented from being distorted or collapsed.

As illustrated in FIGS. 11Ab and 11Bb, a raw material gas of a conductive material such as tungsten or molybdenum is injected into the stacked bodies LMga and LMgb from the slits ST, and the gap layers GP of the stacked bodies LMga and LMgb are filled with the conductive material to form the plurality of word lines WL and the like. Thus, the stacked body LM is formed which includes the stacked bodies LMa and LMb in which the plurality of word lines WL and the like and the plurality of insulating layers OL are alternately stacked one by one.

As described above, the process of forming the intermediate source line BSL from the intermediate sacrificial layer SCN and the process of forming the word line WL from the insulating layer NL are also referred to as replacement processes.

Thereafter, although not illustrated, a conductive layer is filled in the slit ST through an insulating liner layer or the like to form the plate-like contact LI. In addition, a groove is formed which penetrates one or a plurality of conductive layers including the uppermost conductive layer of the stacked body LMb, and the groove is filled with an insulating layer, thereby forming the separation layer SHE that partitions these conductive layers into the pattern of the selection gate line SGD. In addition, the plurality of contacts CC is formed which respectively reaches the word lines WL and the selection gate lines SGD and SGS constituting each step of the staircase structure of the staircase region SR from the upper side of the staircase region SR.

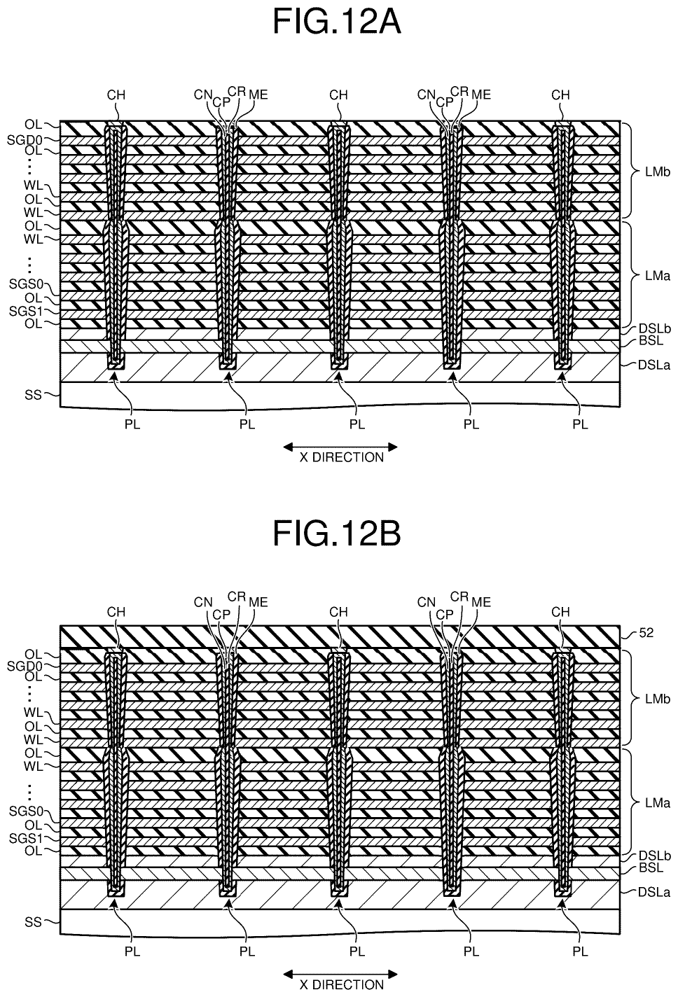

As illustrated in FIG. 12A, the plug CH is formed which penetrates the uppermost insulating layer OL of the stacked body LM and is connected to the cap layer CP at the upper end portion of the pillar PL.

As illustrated in FIG. 12B, the insulating layer 52 covering the stacked body LM is formed.

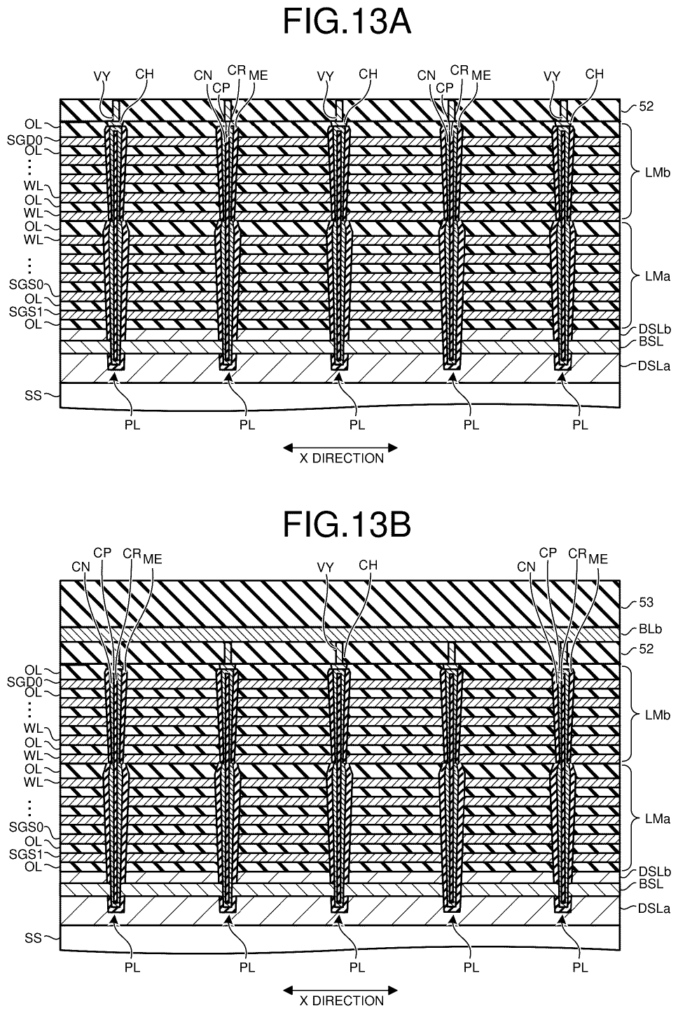

As illustrated in FIG. 13A, the plug VY is formed which penetrates the insulating layer 52 and is connected to the plug CH.

As illustrated in FIG. 13B, a metal layer BLb is formed which covers the insulating layer 52 on which the plug VY is formed. The metal layer BLb is a layer that is later formed in a pattern spaced apart from each other in the X direction and extending in the Y direction to become the bit lines BL. In addition, the insulating layer 53 covering the metal layer BLb is formed. At this point, the insulating layer 53 is formed to be thicker than the insulating layer 53 to be finally included in the semiconductor device 1.

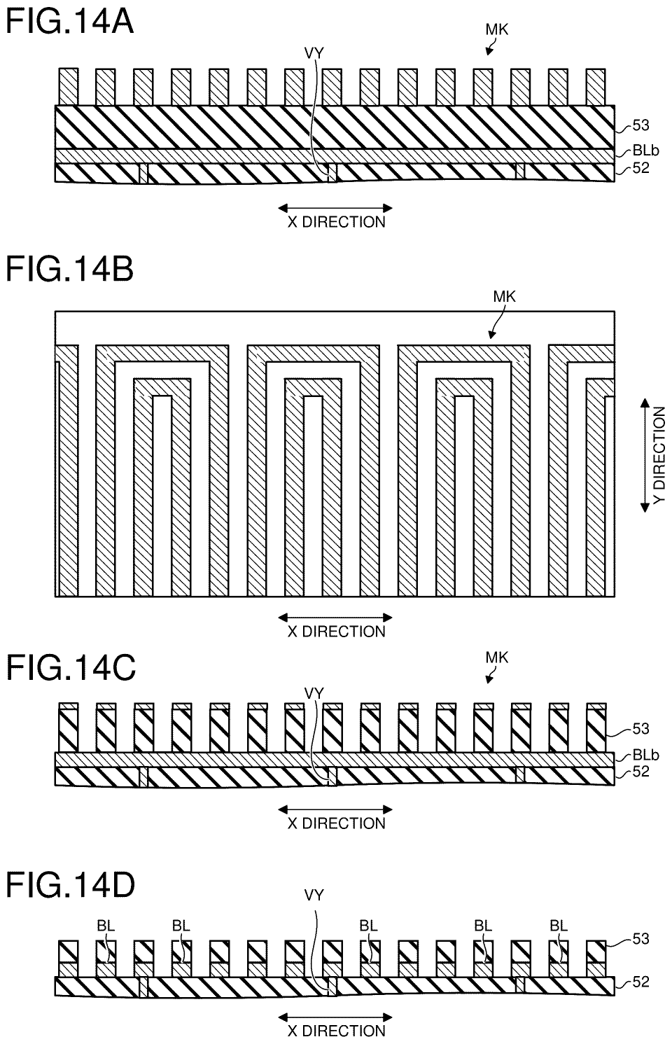

In the following, in FIGS. 14A to 16D, illustration of the stacked body LM below the insulating layer 52, the pillar PL formed in the stacked body LM, and the like is omitted.

As illustrated in FIG. 14A, metal mask patterns MK such as tungsten layers are formed on the insulating layer 53. In the memory region MR where the plurality of pillars PL is disposed, the metal mask patterns MK have a line-and-space pattern in which the patterns are spaced apart from each other in the X direction and extend in the Y direction.

As illustrated in the top view of FIG. 14B, the metal mask patterns MK are connected to each other in a loop shape and terminated at positions separated from the memory region MR by predetermined distances in the Y direction. Such a metal mask pattern MK is formed by, for example, a multi-patterning method.

In the formation of the metal mask pattern MK using the multi-patterning method, a pattern serving as a core material such as an insulating layer is formed in a portion serving as a space of the metal mask pattern MK having a line-and-space pattern. In addition, after the sidewalls of these core materials are covered with a metal layer such as a tungsten layer, the core materials are removed. Thus, the metal layer formed on the sidewalls of the core materials is formed into a metal mask pattern MK having a line-and-space pattern.

By using the multi-patterning method, it is possible to obtain the metal mask pattern MK having a line-and-space pattern which is finer and has a narrower pitch than a pattern serving as a core material.

As illustrated in FIG. 14C, the insulating layer 53 exposed from the metal mask pattern MK is etched to transfer the line-and-space pattern of the metal mask pattern MK to the insulating layer 53.

As illustrated in FIG. 14D, the metal layer BLb is etched using the patterned insulating layer 53 as a mask, and the line-and-space pattern is further transferred to the metal layer BLb to form a plurality of bit lines BL spaced apart from each other in the X direction and extending in the Y direction. Thus, the layer thickness of the insulating layer 53 is reduced to, for example, a layer thickness to be finally included in the semiconductor device 1.

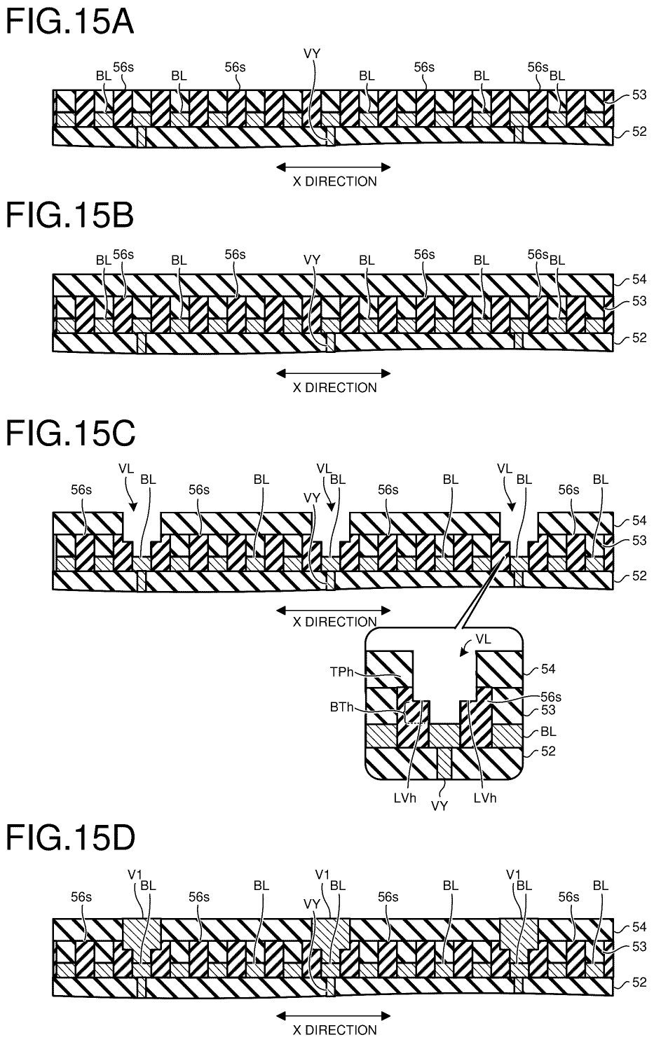

As illustrated in FIG. 15A, an insulating layer 56s such as a silicon nitride layer is formed in the space portion of the insulating layer 53 and the bit line BL which have the line-and-space pattern. That is, the insulating layer 56s extends in the Y direction between a plurality of lines, which is the insulating layer 53 and the bit line BL.

As illustrated in FIG. 15B, the insulating layer 54 covering the entire surfaces of the insulating layers 53 and 56s is formed.

As illustrated in FIG. 15C, via holes VL penetrating through the insulating layers 54, and 53 and reaching the bit lines BL are formed at positions respectively corresponding to the plugs VY connected to the plurality of pillars PL.

The via holes VL are configured such that the diameters of the upper end portions thereof are larger than the widths of the bit lines BL in the X direction, and are formed in the insulating layers 53 and 54, which are silicon oxide layers or the like, using etching conditions having a selection ratio with respect to the insulating layer 56s, which is a silicon nitride layer or the like.

During the formation of the via holes VL, the etched ends of the via holes VL penetrate the insulating layer 54 and reach the upper surfaces of the insulating layers 53 and 56s. At this point, since an etching condition having a selection ratio with respect to the insulating layer 56s is used in the insulating layer 53, thereafter, the etching of the insulating layer 53 proceeds preferentially among the insulating layers 53 and the 56s, and the etching of the insulating layer 56s stagnates.

Thus, at a height position between the upper surfaces of the insulating layers 53 and 56s and the upper surface of the bit line BL, the via hole VL is narrowed to a diameter substantially equal to the distance between the insulating layers 56s in the X direction, that is, the width of the bit line BL in the X direction.

Thus, the via hole VL is formed to have an upper via hole TPh extending downward in the insulating layer 54 and having a diameter larger than the width of the bit line BL in the X direction, and a lower via hole BTh having a diameter smaller than the diameter of the upper via hole TPh and extending downward in the insulating layer 53 to reach the bit line BL. In addition, the via hole VL has a step LVh at a connection portion between the upper via hole TPh and the lower via hole BTh.

At this point, as the selection ratio with respect to the insulating layer 56s is higher, the step LVh is formed at a position closer to the upper surfaces of the insulating layers 53 and 56s.

As illustrated in FIG. 15D, the via hole VL is filled with a conductive layer. Thus, the upper via hole TPh becomes an upper via TPV, the lower via hole BTh becomes a lower via BTv, and the via V1 having the step LVv (see FIG. 2D) is formed.

As described above, by forming the via hole VL while maintaining the selection ratio with respect to the insulating layer 56s, the via V1 having a diameter larger than the width of the bit line BL in the X direction can be connected to the bit line BL having a narrow pitch in a self-aligned manner, for example. That is, it is not necessary to form the via hole VL having a fine diameter corresponding to the width of the bit line BL over the entire via hole, and even when the via hole VL is formed in a state of being misaligned with the bit line BL, interference between the bit line BL and the via V1 that are adjacent to each other is prevented.

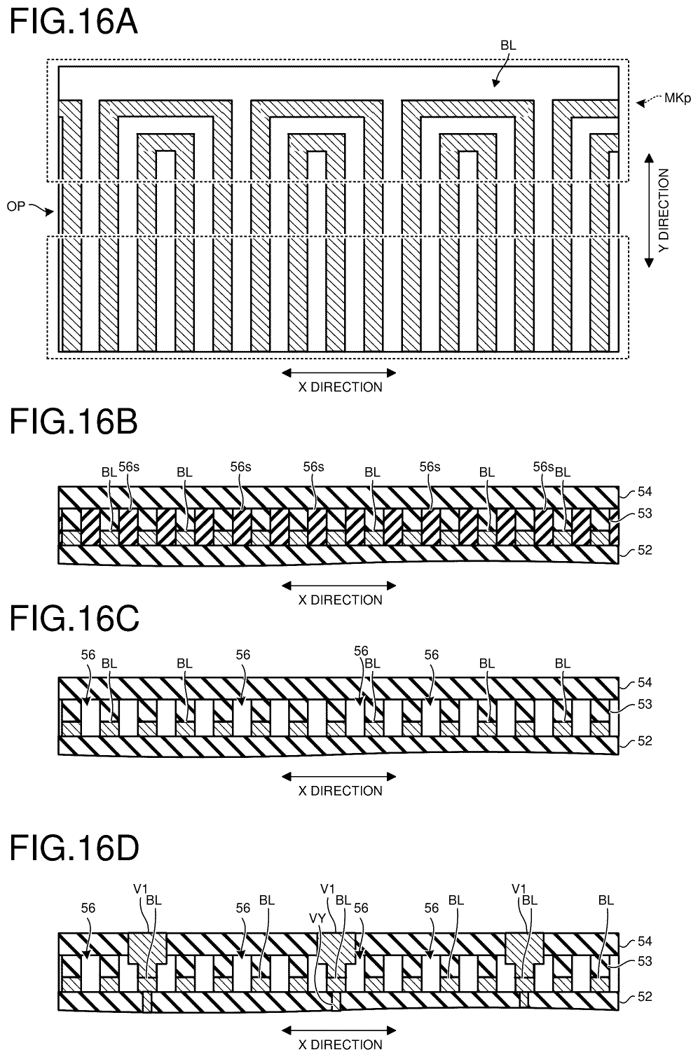

Thereafter, as illustrated in FIGS. 16A to 16D, a process called loop cut is performed which individually separates the bit lines BL connected to each other in a loop shape.

As illustrated in FIG. 16A, a mask pattern MKp such as a photoresist layer having an opening OP is formed in the vicinity of a region which is separated from the memory region MR by a predetermined distance in the Y direction and in which the above-described metal mask pattern MK is transferred and the bit lines BL are connected to each other in a loop shape.

In addition, the insulating layer 54, the insulating layers 53 and 56s, and the bit line BL exposed from the opening OP of the mask pattern MKp are removed and the insulating layer 52 below the bit line BL is exposed, whereby the bit line BL on the memory region MR side is cut off from the loop-shaped portion and separated into the individual bit lines BL.

As illustrated in FIG. 16B, by removing the insulating layers 54, 53, and 56s, and the bit line BL, cut surfaces of these layers are exposed in the opening OP of the mask pattern MKp.

As illustrated in FIG. 16C, a chemical solution is permeated from the cut surfaces of the insulating layers 54, 53, and 56s, and the bit line BL, and the entirety of insulating layer 56s which is, for example, a silicon nitride layer or the like is removed by wet etching or the like. Thus, a plurality of air gap layers 56 extending in the Y direction is formed between and along the bit lines BL and the insulating layers 53, which have a line-and-space pattern.

As illustrated in FIG. 16D, the entirety of insulating layer 56s is removed by wet etching or the like, whereby the air gap layers 56 are also formed on both sides in the X direction of the via V1 disposed in the memory region MR and connected to the pillar PL via the bit line BL or the like.

Then, the insulating layer 55 is formed on the upper surface of the insulating layer 54, and the upper layer wiring M1 connected to the individual vias V1 is formed in the insulating layer 55. In addition, an electrode pad or the like for electrical conduction with the peripheral circuit CBA is formed on the uppermost surface of the insulating layer 50 including the insulating layers 52 to 55 and the like.

In addition, the peripheral circuit CBA is formed on the semiconductor substrate SB which is different from the support substrate SS on which the stacked body LM is formed, and is covered with the insulating layer 40. In the insulating layer 40, a contact, a via, wiring, or the like that draws out the peripheral circuit CBA to the surface of the insulating layer 40 is formed, and is connected to an electrode pad or the like formed on the upper surface of the insulating layer 40.

Subsequently, the support substrate SS and the semiconductor substrate SB are bonded to each other with the insulating layers 50 and 40 included in the support substrate and the semiconductor substrate, respectively, and the electrode pads in the insulating layers 50 and 40 are connected to each other. Thereafter, the support substrate SS is removed to expose the source line SL, and the electrode film EL is connected via the insulating layer 60 in which the plug PG is formed.

Thus, the semiconductor device 1 of the embodiment is manufactured.

### (Overview)

In order to increase the storage capacity of a semiconductor device such as a three-dimensional nonvolatile memory, an attempt has been made to increase the arrangement density of pillars that three-dimensionally generate memory cells. Accordingly, the bit lines connected to the pillars and the wiring and the like in the layers above the bit lines are also increased in density. As described above, by reducing the pitch between the wirings, the capacitance between the vias connecting the wirings and the wirings increases, and it becomes difficult to secure the breakdown voltage.

According to the semiconductor device 1 of the embodiment, included is the plurality of vias V1 extending from the plurality of upper layer wirings M1 to the plurality of bit lines BL between the plurality of air gap layers 56 and respectively connecting the plurality of bit lines BL and the plurality of upper layer wirings M1. Thus, the breakdown voltage between the bit line BL having a narrow pitch and the via V1 can be secured.

According to the semiconductor device 1 of the embodiment, the plurality of vias V1 each includes: an upper via TPv connected to any one of the plurality of upper layer wirings M1 and extending above the plurality of air gap layers 56 to the plurality of bit lines BL, the upper via having a diameter larger than the width of each of the plurality of bit lines BL in the X direction intersecting the extending direction of the plurality of bit lines BL; and a lower via BTV extending at the height position of the plurality of air gap layers 56 and connected to any one of the plurality of bit lines BL the lower via having a diameter smaller than the diameter of the upper via TPV.

Such a structure of the via V1 can be obtained by forming the via hole VL while taking a selection ratio with respect to the insulating layer 56s which is later removed to become the air gap layer 56. Thus, the plurality of vias V1 can be connected to the bit lines BL having a narrow pitch in a self-aligned manner.

According to the semiconductor device 1 of the embodiment, the step LVv of the plurality of vias V1 protrudes into the plurality of air gap layers 56, respectively. Thus, the breakdown voltage between the bit line BL having a narrow pitch and the via V1 can be further secured.

According to the semiconductor device 1 of the embodiment, the diameter of the lower via BTv is substantially equal to the width of each of the plurality of bit lines BL in the X direction. Thus, the via V1 is prevented from interfering with the bit line BL adjacent in the X direction to the bit line BL to which the via V1 is connected.

According to the semiconductor device 1 of the embodiment, included is a plurality of pillars PL each having a channel layer CN extending within the stacked body LM in the stacking direction of the stacked body LM and connected to any one of the plurality of bit lines BL, and arranged in a plurality of columns in the Y direction intersecting the X direction. As described above, the bit line BL having a narrow pitch and the upper layer wiring M1, which correspond to the pillar PL increased in density, can be connected to each other with low capacitance and high breakdown voltage by the via V1 of the embodiment.

Note that the above-described embodiment describes that the semiconductor device 1 includes the stacked body LM having a two-tier structure in which the two stacked bodies LMa and LMb are stacked vertically. However, the configuration of the stacked body is not limited to two tiers, and may be one tier, or may be three or more tiers.

In addition, the above-described embodiment describes the pillar PL or the like is connected to the source line SL on the side surface of the channel layer CN, but is not limited thereto. For example, the pillar may be configured such that the memory layer on the bottom surface of the pillar is removed and the lower end portion of the channel layer is connected to the source line.

In addition, the above-described embodiments describes that the peripheral circuits CBA and CUA are disposed above or below the stacked body LM. However, the peripheral circuits may be disposed in the same layer as the stacked body. In this case, the stacked body can be formed at a position different from the peripheral circuits on the semiconductor substrate on which the peripheral circuits are formed.

In addition, the above-described embodiment describes that the via V1 formed in a self-aligned manner and the air gap layer 56 disposed around the via are used for the connection structure between the bit line BL and the upper layer wiring M1. However, the configuration of the above-described embodiment may be applied to other portions of the above-described semiconductor device 1, such as a connection structure between the contact CC disposed in the staircase region SR and an upper layer wiring thereof.

In addition, the above-described embodiment describes that the above-described configuration is applied to the semiconductor device 1 such as a three-dimensional nonvolatile memory, but there is a case where other semiconductor devices such as a dynamic random access memory (DRAM) also have a wiring structure with a narrow pitch, and the configuration of the above-described embodiment can also be applied to these structures.

While certain embodiments have been described, these embodiments have been presented by way of example only, and are not intended to limit the scope of the present disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a plurality of first wiring layers arranged at a predetermined distance from each other;
a plurality of air gap layers respectively disposed between the plurality of first wiring layers so as to protrude from a height position of the first wiring layer, and extending along the first wiring layer;
a plurality of second wiring layers disposed above the plurality of first wiring layers; and
a plurality of vias extending from the plurality of second wiring layers to the plurality of first wiring layers between the plurality of air gap layers and connecting the plurality of first and second wiring layers, respectively, wherein
the plurality of vias each includes:
an upper structure connected to any one of the plurality of second wiring layers and extending above the plurality of air gap layers toward the plurality of first wiring layers, the upper structure having a first diameter larger than a width of each of the plurality of first wiring layers in a first direction intersecting an extending direction of the plurality of first wiring layers; and
a lower structure extending at a height position of the plurality of air gap layers and connected to any one of the plurality of first wiring layers, the lower structure having a second diameter smaller than the first diameter.

2. The semiconductor device according to claim 1, wherein
the plurality of vias each has a step at a connection portion between the upper structure and the lower structure.

3. The semiconductor device according to claim 2, wherein
the plurality of vias each has the connection portion between the upper structure and the lower structure at a height position between an upper surface of the plurality of air gap layers and an upper surface of the plurality of first wiring layers, and
the step protrudes into the plurality of air gap layers, respectively.

4. The semiconductor device according to claim 1, wherein
the second diameter of the lower structure is equal to a width of each of the plurality of first wiring layers in the first direction.

5. The semiconductor device according to claim 1, further comprising:
a stacked body that is disposed below the plurality of first wiring layers and in which a plurality of conductive layers and a plurality of insulating layers are alternately stacked one by one; and
a plurality of pillars each having a semiconductor layer extending in the stacked body in a stacking direction of the stacked body and connected to any one of the plurality of first wiring layers, and arranged in n columns (n is an integer of 2 or more) in a second direction intersecting the first direction.

6. The semiconductor device according to claim 5, further comprising:
a first plate-like portion extending in the stacked body in the first direction and the stacking direction; and
a second plate-like portion extending in the stacked body in the first direction and the stacking direction at a position separated from the first plate-like portion in the second direction, wherein
the plurality of pillars is disposed in a region between the first and second plate-like portions.

7. The semiconductor device according to claim 5, further comprising:
a first plate-like portion extending in the stacked body in the first direction and the stacking direction;
a second plate-like portion extending in the stacked body in the first direction and the stacking direction at a position separated from the first plate-like portion in the second direction; and
a plurality of separation layers penetrating at least an uppermost conductive layer of the plurality of conductive layers, and extending in the first direction at positions separated from each other in the second direction in a region of the stacked body between the first and second plate-like portions, wherein
the plurality of pillars is disposed in a region between a separation layer adjacent to the first plate-like portion in the second direction among the plurality of separation layers, and the first plate-like portion, or the plurality of pillars is disposed in a region between two separation layers adjacent to each other in the second direction among the plurality of separation layers.

8. The semiconductor device according to claim 7, wherein
among the plurality of pillars, pillars belonging to a same column among the columns are connected to every n-th first wiring layer among the plurality of first wiring layers arranged in the first direction.

9. The semiconductor device according to claim 8, wherein
among the plurality of pillars, pillars belonging to the columns adjacent to each other are disposed such that center points of the pillars do not overlap each other in the second direction when viewed from the stacking direction.

10. The semiconductor device according to claim 9, wherein
the plurality of pillars is arranged in a staggered manner when viewed from the stacking direction.

11. A method of manufacturing a semiconductor device, wherein
stacking a first metal layer and a first insulating layer in this order,
forming a plurality of grooves penetrating the first insulating layer and the first metal layer, so as that a plurality of first wiring layers arranged at a predetermined distance from each other by the plurality of grooves is formed in a first direction along a surface direction of the first metal layer,
filling the plurality of grooves with a second insulating layer,
forming a third insulating layer covering the first and second insulating layers,
forming a plurality of vias penetrating the third insulating layer and the first insulating layer and respectively connected to the plurality of first wiring layers, and
removing the second insulating layer filled between the plurality of first wiring layers from a position separated from the plurality of vias in a second direction intersecting the first direction, so as that a plurality of air gap layers is respectively formed on both sides of the plurality of vias in the first direction,
the forming the plurality of vias includes:
while keeping a selectivity to the second insulating layer, penetrating the third and first insulating layers, so as to a plurality of via holes having a first diameter larger than a width of each of the plurality of first wiring layers in the first direction is formed; and
filling the plurality of via holes with a conductive layer.

12. The method of manufacturing a semiconductor device according to claim 11, wherein
the forming the plurality of via holes includes:
respectively forming an upper via hole extending above the second insulating layer toward the plurality of first wiring layers, the upper via hole having the first diameter; and
while keeping the selectivity to the second insulating layer, respectively forming a lower via hole extending at a height position of the second insulating layer and respectively connecting the lower via hole to the plurality of first wiring layers, the lower via hole having a second diameter smaller than the first diameter.

13. The method of manufacturing a semiconductor device according to claim 12, wherein
forming the plurality of via holes each having a step at a connection portion between the upper via hole and the lower via hole.

14. The method of manufacturing a semiconductor device according to claim 11, wherein
the forming the plurality of air gap layers includes:
removing a part of the first to third insulating layers at the position separated from the plurality of vias in the second direction; and
removing an entirety of the second insulating layer from a cross-section of the second insulating layer exposed by a removal of the first and third insulating layers.

15. The method of manufacturing a semiconductor device according to claim 14, wherein
the forming the plurality of first wiring layers includes:
forming the plurality of first wiring layers in a loop shape; and
removing a part of the plurality of first wiring layers when removing the first to third insulating layers to separate the plurality of first wiring layers individually.
